(19) United States
(12) Patent Application Publication
(10) Pub. No.: US 2026/0332162 A1
(43) Pub. Date: Oct. 22, 2026

(54) ELECTRONIC DEVICE AND METHOD OF PERFORMING DATA COMPRESSION

(71) Applicant: SAMSUNG ELECTRONICS CO., LTD., Suwon-si (KR)

(72) Inventors: Chansol Hwang, Suwon-si (KR); Paul Oh, Suwon-si (KR); Seunghoon Jee, Suwon-si (KR); Dokwan Oh, Suwon-si (KR); Junhee Lee, Suwon-si (KR)

(73) Assignee: SAMSUNG ELECTRONICS CO., LTD., Suwon-si (KR)

(21) Appl. No.: 19/530,806

(22) Filed: Feb. 5, 2026

(30) Foreign Application Priority Data
Apr. 22, 2025 (KR) 10-2025-0052634
Jul. 30, 2025 (KR) 10-2025-0104501

(51) Int. Cl. H03M 7/30; H03K 19/20

(52) U.S. Cl. CPC H03M 7/6011; H03K 19/20

(57) ABSTRACT

An electronic device includes a compression device that generates a compressed bitstream from a data stream, the compressed bitstream representing a target symbol from an input bitstream representing an input symbol from the data stream including the input symbol and the target symbol. The compression device includes a compression information generator that generates compression-related information on the target symbol from the input bitstream, based on a logic gate network including plural logic gates arranged for data compression, and a coder that generates the compressed bitstream corresponding to the target symbol based on the compression-related information.

### CROSS-REFERENCE TO RELATED APPLICATIONS

This application claims priority to Korean Patent Application No. 10-2025-0052634, filed on Apr. 22, 2025, and to Korean Patent Application No. 10-2025-0104501, filed on Jul. 30, 2025, in the Korean Intellectual Property Office, the entire disclosures of each of which being incorporated by reference herein for all purposes.

### BACKGROUND

### 1. Field

The following description relates to data compression.

### 2. Description of Related Art

Data compression technology plays a key role in contemporary information processing and communication systems and has been continuously developed to save storage space and improve data transmission efficiency. For example, a data compression method may be typically implemented by removing redundancy in information by analyzing statistical characteristics of input data or retaining only information in a specific situation.

### SUMMARY

According to an aspect of one or more embodiments, an electronic device may comprise a compression device that is configured to generate a compressed bitstream from a data stream, the compressed bitstream representing a target symbol from an input bitstream representing an input symbol from the data stream including the input symbol and the target symbol. The compression device may comprise a compression information generator that is configured to generate compression-related information on the target symbol from the input bitstream, based on a logic gate network including a plurality of logic gates arranged for data compression; and a coder that is configured to generate the compressed bitstream corresponding to the target symbol based on the compression-related information.

According to an embodiment, the compression-related information may include a score corresponding to a probability that the bitstream belongs to each of bit combinations according to a coding system of a symbol.

According to an embodiment, the compression information generator may include a raw probability score generator determining a score to be the compression-related information, wherein the score may correspond to a probability based on counting a number of predetermined bit values in a bit group corresponding to each of bit combinations.

According to an embodiment, the compression information generator may include a raw probability score generator determining a score corresponding to a probability based on a scalar value that is determined using a bit position and a bit value of a bit group corresponding to each of bit combinations.

According to an embodiment, the coder may determine a probability distribution function (PDF) of bit combinations, based on a score corresponding to a probability.

According to an embodiment, a number of bits of the compressed bitstream may be less than a number of bits of a bitstream representing one of symbols input to the logic gate network.

According to an embodiment, each of the plurality of logic gates of the logic gate network may perform a binary logic operation.

According to an embodiment, at least one of a type of logic gates of the logic gate network or a connection among the logic gates may be determined based on training a differentiable logic gate network corresponding to the logic gate network.

According to an embodiment, the compression device may generate the compressed bitstream corresponding to a symbol of a data stream received from the host device in response to a write request of a host device, and may store compressed data including the compressed bitstream in a memory cell.

According to an embodiment, the compression device may generate the compressed bitstream corresponding to a symbol of a data stream loaded from a memory cell in response to a read request of a host device, and provides compressed data including the compressed bitstream to the host device.

According to another aspect of one or more embodiments, a method of operating an electronic device may comprise generating compression-related information on a target symbol of a data stream from an input bitstream that represents an input symbol of the data stream, based on a logic gate network including a plurality of logic gates arranged for data compression; and generating a compressed bitstream that corresponds to the target symbol, based on the compression-related information.

According to yet another aspect of one or more embodiments, a non-transitory computer-readable storage medium stores instructions that, when executed by a processor, cause the processor to perform the method of operating the electronic device.

Additional aspects of embodiments will be set forth in part in the description which follows and, in part, will be apparent from the description, or may be learned by practice of the disclosure.

### BRIEF DESCRIPTION OF THE DRAWINGS

The above and/or other aspects will be more apparent by describing certain embodiments with reference to the accompanying drawings, in which:

FIG. 1 illustrates a configuration of an electronic device for generating a compressed bitstream, according to an embodiment;

FIG. 2 is a flowchart of a method of generating a compressed bitstream, according to an embodiment;

FIG. 3 is a block diagram of a configuration of a compression information generator and a coder according to an embodiment;

FIG. 4 illustrates a bitstream generator according to an embodiment;

FIG. 5 illustrates an operation according to a logic gate network according to an embodiment;

FIG. 6 illustrates an example of counting a number of bits as a raw probability score according to an embodiment;

FIG. 7 illustrates an example of determining a scalar value as a raw probability score according to an embodiment;

FIG. 8 illustrates an example of generating a compressed bitstream from a raw probability score according to an embodiment;

FIG. 9 illustrates training using a differentiable logic gate network according to an embodiment; and

FIG. 10 illustrates an example of a configuration of an electronic device according to an embodiment.

### DETAILED DESCRIPTION

The following detailed structural or functional description is provided as an example only and various alterations and modifications may be made to the embodiments. Accordingly, the embodiments are not to be construed as limited to the disclosure and should be understood to include all changes, equivalents, and replacements within the idea and the technical scope of the disclosure.

Although terms, such as “first”, “second”, and the like are used to describe various components, the components are not limited to the terms. These terms should be used only to distinguish one component from another component. For example, a “first” component may be referred to as a “second” component, and similarly, a “second” component may also be referred to as a “first” component.

It should be noted that if it is described that one component is “connected”, “coupled”, or “joined” to another component, a third component may be “connected”, “coupled”, and “joined” between the first and second components, although the first component may be directly connected, coupled, or joined to the second component.

As used herein, the singular form is intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

As used herein, “A or B”, “at least one of A and B”, “at least one of A or B”, “A, B or C”, “at least one of A, B and C”, and “at least one of A, B, or C,” each of which may include any one of the items listed together in the corresponding one of the phrases, or all possible combinations thereof. For example, as used in this specification, a phrase using the form “at least one of A, B, or C” includes within its scope “only A”, “only B”, “only C”, “A and B”, “A and C”, “B and C” and “A, B, and C.”

Unless otherwise defined, all terms, including technical and scientific terms, used herein have the same meaning as commonly understood by one of ordinary skill in the art to which the present disclosure pertains. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

As a data compression method, statistical modeling and dictionary based compression may be used. As a model for predicting a probability distribution, an artificial intelligence-based neural network (NN) structure may be used. For example, a probabilistic regression model (regressor) may be built using an NN structure, such as multi-layer perceptron (MLP) or a convolutional NN (CNN), and the regressor may be integrated into a compression algorithm.

Hereinafter, embodiments will be described in detail with reference to the accompanying drawings. When describing the embodiments with reference to the accompanying drawings, like reference numerals refer to like elements and a repeated description related thereto will be omitted.

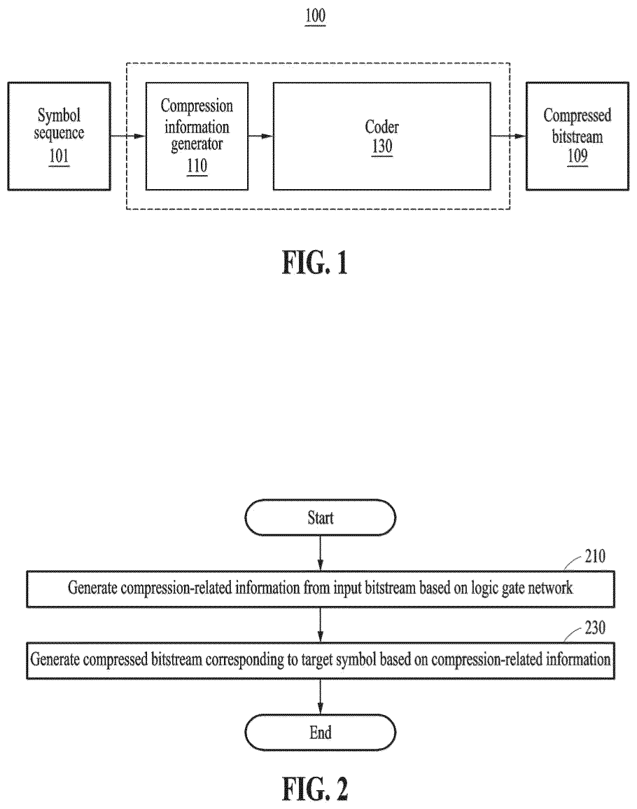

FIG. 1 illustrates a configuration of an electronic device for generating a compressed bitstream according to an embodiment.

The electronic device according to an embodiment may include a compression device 100. The compression device 100 may be embedded in the electronic device as an application-specific integrated circuit (ASIC). The electronic device may compress a data stream using the compression device 100. For example, the data stream may include a symbol sequence 101. The data stream (or the symbol sequence 101) may include a plurality of symbols. A symbol may be a unit for representing information. The symbol may be represented as a bitstream. Herein, an example in which one symbol is represented as a 1-byte bitstream (e.g., an 8-bit bitstream) is mainly described by way of illustration.

The compression device 100 may generate a compressed bitstream 109 from the symbol. For example, the compression device 100 may generate a compressed bitstream that represents a target symbol from an input bitstream that represents an input symbol in a data stream including the input symbol and the target symbol. The target symbol may indicate a symbol to be compressed. The input symbol may indicate a symbol referenced to compress the target symbol. For example, when the data stream is the symbol sequence 101 that sequentially includes symbols A, B, C, and D, symbol D may be a target symbol and the other preceding symbols A, B, and C may be input symbols. The compression device 100 may compress a subsequent target symbol (e.g., symbol D) with reference to the input symbols (e.g., symbols A, B, and C). The compression device 100 may include a compression information generator 110 and a coder 130.

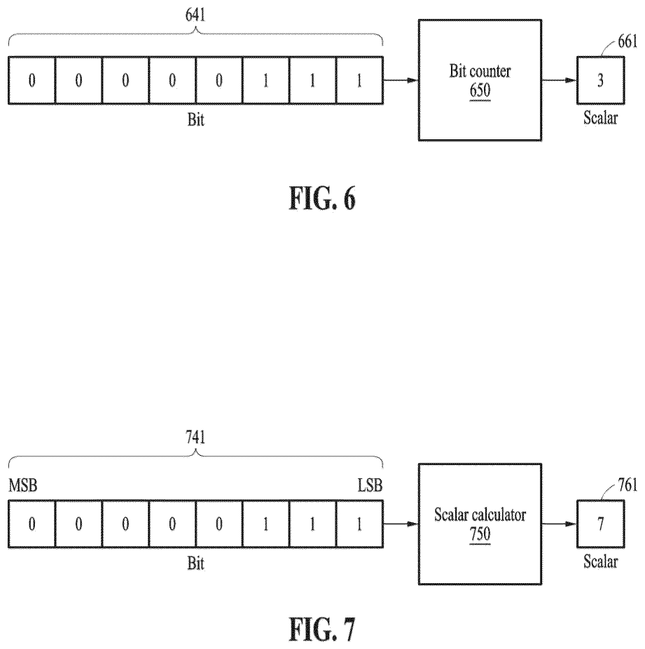

The compression information generator 110 may generate compression-related information from the input symbol. The compression-related information may be information used for generating the compressed bitstream 109 corresponding to the target symbol and may include information indicating a probability that each symbol occurs subsequent to the preceding input symbol. The compression-related information may include, for example, information that serves as a basis for determining a probability distribution (e.g., a probability distribution function (PDF) or a cumulative distribution function (CDF)) used for entropy coding. For example, the compression-related information may include information (e.g., a raw probability score) in which a bitstream corresponds to each probability of bit combinations according to a coding system of the symbol sequence 101. The bit combination may be a sequence (e.g., a bit sequence) of a combination of bit values according to the coding system to represent a symbol. For example, a coding system for representing an 8-bit bit sequence may include a total of 2\hat{ }8=256 bit combinations from “0000 0000”, “0000 0001”, to “1111 1111”, as the number of possible symbols. The compression-related information may include 256 raw probability scores for 256 bit combinations. For reference, the example assumes that each of the bit combinations individually represents a symbol, but embodiments are not limited thereto. A symbol may be assigned to only some bit combinations among the bit combinations that may be represented as n bits, or a symbol may be represented as n+1 bits or 2n bits. A length n of the input bit sequence and a number g of possible symbols to be represented in compression may vary depending on a configuration, and a description related thereto is provided in association with Equation 1 below. The raw probability score may be a score before being normalized to a probability value, and examples of the raw probability score may be a summed bit count for each bit combination in FIG. 6 and a scalar value for each bit combination in FIG. 7.

The compression information generator 110 may include a logic gate network. The logic gate network may be a network (or array) in which a plurality of physical logic gates is physically arranged. The logic gate network may be configured and disposed to output, from a number of input symbols, information related to the probability that each symbol occurs subsequent to the input symbols according to the coding system. The number of input symbols may be predetermined.

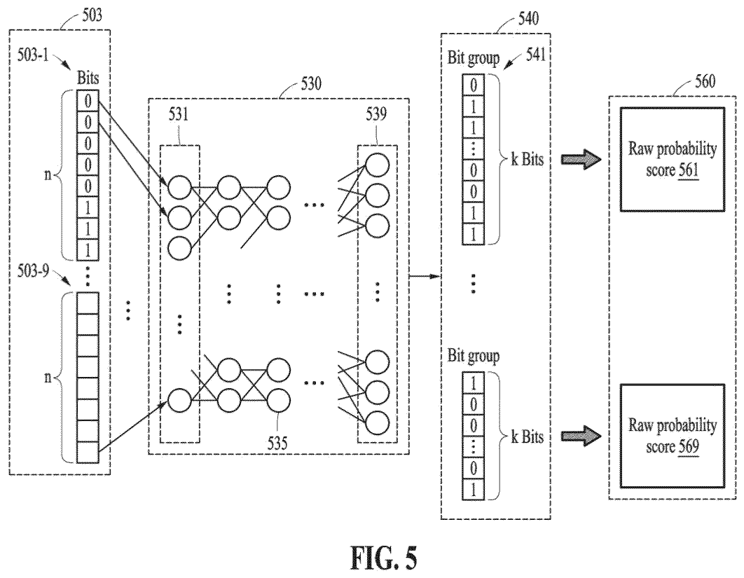

In an embodiment, the logic gate network may receive a bitstream as an input and may output bit values used for computing each probability (or raw probability score) of bit combinations according to the coding system. A bitstream (e.g., an input bitstream) input to the logic gate network may be a bitstream that represents the input symbols in the symbol sequence 101. Bit values (e.g., output bit values) output from the logic gate network may be used for computing the probability (or raw probability score) that each symbol occurs subsequent to the input symbol. The bit values (e.g., the output bit values) output from the logic gate network may be, for example, grouped or partitioned into bit combinations according to the coding system. For example, since, as described above, an 8-bit coding system includes 256 bit combinations, the output bit values of the logic gate network may be classified into 256 bit groups. However, this example is for ease of understanding, and embodiments are not limited thereto. For an n-bit coding system, m output bit values of the logic gate network may be classified into g bit groups. The values n, m, and g may be integers greater than or equal to 1 and may be determined according to a configuration. The output bit values corresponding to one of the plurality of bit combinations may be a bit sequence that directly or indirectly represents the probability (or raw probability score) of the corresponding bit combination. The output bit value is described with reference to FIG. 5 below.

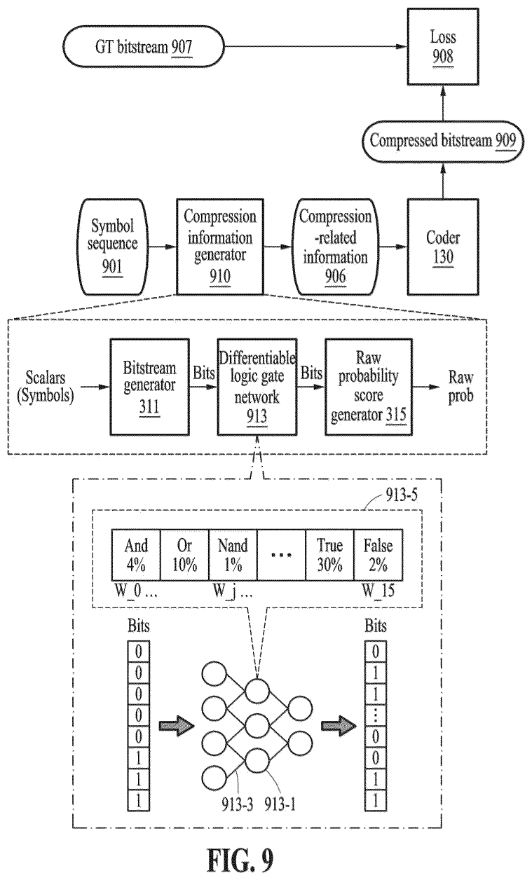

According to an embodiment, the logic gate network may include logic gates of a type based on specific machine learning for a target application. The type may be determined. The present disclosure mainly describes an example of the logic gate network including logic gates arranged for data compression as an example of the target application, but embodiments are not limited thereto. The machine learning for determining the logic gate network is described with reference to FIG. 9 below. In an embodiment, the logic gate network may be embedded in the electronic device as an application-specific integrated circuit (ASIC). In some embodiments, the logic gate network may be embedded in the electronic device as a portion of the ASIC implementing the compression device 100.

The coder 130 may generate the compressed bitstream 109 from the compression-related information. For example, the coder 130 may generate probability information (e.g., the probability distribution) corresponding to the input symbols based on the compression-related information. The probability information corresponding to the input symbols may include a probability distribution of a symbol that may occur subsequent to the input symbol. The coder 130 may generate the compressed bitstream 109 corresponding to the target symbol based on entropy coding using the probability information. For example, the coder 130 may convert the compression-related information output from the logic gate network into the probability via an operation according to a nonlinear function (e.g., a softmax function). The coder 130 may generate the result (e.g., the compressed bitstream) of compressing the target symbol by performing entropy coding (e.g., arithmetic coding) using the converted probability.

FIG. 2 is a flowchart of a method of generating a compressed bitstream, according to an embodiment.

According to an embodiment, a compression device (e.g., the compression device 100 of FIG. 1) may generate a compressed bitstream that represents a target symbol from an input bitstream that represents an input symbol in a data stream including a plurality of symbols (e.g., the input symbol and the target symbol).

For example, in operation 210, the compression device may generate compression-related information on the target symbol from the input bitstream based on a logic gate network. The logic gate network may include a plurality of logic gates arranged for data compression.

In operation 230, the compression device may generate a compressed bitstream corresponding to the target symbol based on the compression-related information.

The electronic device according to an embodiment may perform lossless or low-loss data compression using the logic gate network. The present disclosure mainly describes an example of using a logic gate network determined by training based on a data set for a data compression application, but embodiments are not limited thereto. In addition to data compression, a logic gate network determined by training based on a data set for other applications may be used. In various applications, an ultra-lightweight network at a logic gate level may be used. As described above, when a network at a gate level is determined, an ASIC may be produced without an additional procedure to optimize an arithmetic and logical unit (ALU). The overhead of hardware production may be reduced.

For example, in association with data compression, in a comparative example using a neural network-based regressor to estimate the probability of a target symbol, quantization of the neural network to produce the ASIC and hardware optimization for the ALU to implement the neural network may be required. In addition, in the softmax operation for probability estimation, an additional operator may be required for an exponential function operation.

By contrast, according to an embodiment, as described below, since a logic gate network for inference is determined based on training on a differentiable logic gate network, each node of the logic gate network for inference may be fixed to one logic gate. Since the logic gate network for inference is already a fully quantized network, additional quantization may not be required. In an embodiment, performance degradation due to quantization may not occur.

Moreover, in an embodiment, since a hardware optimization process for the ALU is omitted, an error in the computed hardware size (e.g., the hardware area) for implementing the logic gate network may be reduced or removed. When fabricating the logic gate network according to an embodiment into a chip, such as an ASIC, only a layout of the logic gate may be considered. Accordingly, a separate process of operation optimization for the ALU may not be required.

The electronic device according to an embodiment may include fewer ALUs for performing specific operations than the comparative example of the related art. For example, the operation of determining a raw probability score based on the logic gate network described above may not require the intervention of the ALU (e.g., a matrix operator and a multiplier). The electronic device may determine the raw probability score using circuitry in which only logic gates are arranged. As described below, the electronic device may compute a probability distribution from the raw probability score using a general-purpose processor and may generate a compressed bitstream from the computed probability distribution.

To implement ultra-low latency data compression, a recurrent architecture and a skip connection architecture may be excluded. Since the recurrent architecture and the skip connection architecture do not exist in the logic gate network according to an embodiment, the electronic device may perform ultra-low latency data compression.

In an embodiment, an operation corresponding to an exponential function in a nonlinear function (e.g., a softmax function) to convert the output from the logic gate network into a probability may be implemented as a look-up table (LUT). This implementation as a LUT is possible because the output from the logic gate network may be fully quantized.

Table 1 below shows a comparison between a comparative example and an embodiment.

TABLE 1

| 2 nm process | Comparative example | Embodiment |
|---|---|---|
| GCR | 3.56 | 3.66 |
| Area size | 49,404 | 31,134 |
| Core | 33,156 | 27,567 |
| SRAM | 15,668 | 2,987 |
| AC | 580 | 580 |

The logic gate network according to an embodiment may have a higher geometric compression ratio (GCR) with a smaller area size compared to the comparative example. In addition, the area size of the comparative example in Table 1 is an estimated value and may be computed before optimizing the ALU. The area size estimated in the comparative example may be significantly different from the actual area size. The area size of the logic gate network according to an embodiment may be a value converted from the number of transistors of the logic gate included in the logic gate network. Accordingly, an area size error expected in hardware implementation in an embodiment may be relatively less than the area size error expected in the comparative example.

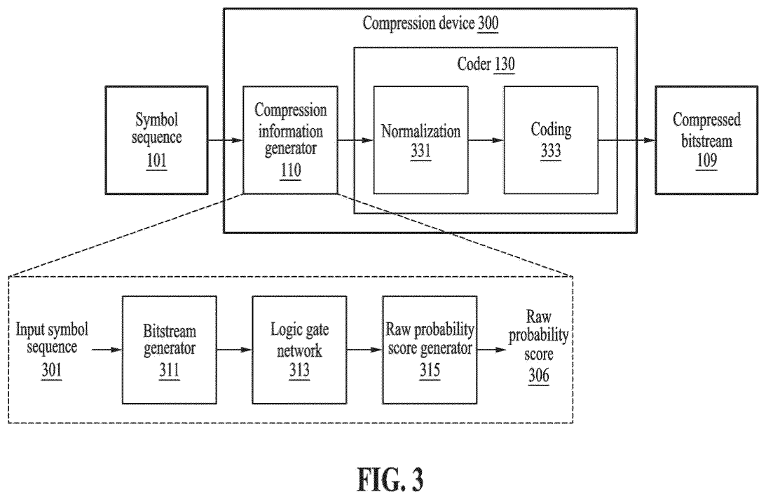

FIG. 3 is a block diagram of a configuration of a compression information generator and a coder. according to an embodiment.

A compression device 300 according to an embodiment may generate the compressed bitstream 109 from the symbol sequence 101. In an embodiment, the compression device 300 may correspond to the compression device 100 of FIG. 1. As described below, the compression device 300 may be included in the electronic device. The compression device 300 may generate an output having fewer bits than the bit count of the symbol. The bit count of the compressed bitstream 109 may be less than a bit count of a bitstream that represents one of symbols input to a logic gate network 313. For example, the symbol sequence 101 shown in FIG. 3 may be “ABCD”. In the symbol sequence 101, an input symbol sequence 301 may be “ABC”, and a target symbol may be “D”. Symbol A, which is one of the symbols of the input symbol sequence 301, may be represented as an n-bit bitstream. The compressed bitstream 109 may be represented as y bits. Here, y may be an integer greater than or equal to 1, and n may be an integer greater than y.

The compression information generator 110 may include a bitstream generator 311, the logic gate network 313, and a raw probability score generator 315.

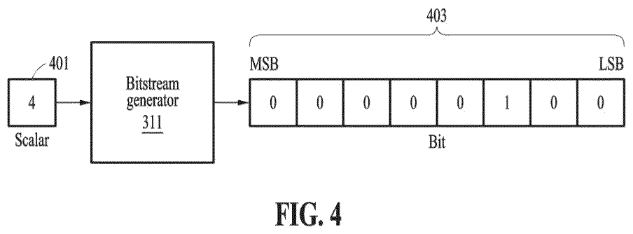

The bitstream generator 311 may convert the input symbol sequence 301 into an input bitstream. Each symbol (e.g., an input symbol) of the input symbol sequence 301 may be a symbol represented as a scalar value. The input bitstream may be a bitstream representing the input symbol sequence 301, and for example, may be a z bit sequence, where z represents the number of input symbols×n bits. For reference, although an example in which the bitstream generator 311 is included in the compression information generator 110 is described with reference to FIG. 3, embodiments are not limited thereto. The compression device 300 may receive a bitstream representing the symbol sequence 101 or the input symbol sequence 301. An example of the bitstream generator 311 is described with reference to FIG. 4 below.

The logic gate network 313 may be a network (or circuitry) including a plurality of logic gates and may generate output bit values that serve as a basis for determining a probability (or a raw probability score 306) of bit combinations of the coding system from the input bitstream. As described above, the output bit values may be grouped by bit combinations according to the coding system (e.g., an original coding system) and may indicate a value that serves as a basis for determining the probability (or the raw probability score 306) of bit combinations that will occur subsequent to input symbols. The output bit values grouped for one of bit combinations may indicate a value (e.g., a bit count or a scalar value) used for computing a distribution of probabilities that the bit combination occurs subsequent to the input symbols. For example, the output bit values may be used to compute the length of a probability interval occupied by the bit combination in the probability distribution. According to an embodiment, the probability distribution may be a distribution of probabilities that a plurality of symbols according to the coding system occurs subsequent to the input symbols. When the length of a bitstream that represents a single symbol in the original coding system is n bits (e.g., 8 bits), the number of bit combinations for subsequent symbols that may be represented as n bits may be g. For example, the number g of bit combinations may be the number of possible symbols to be compressed. When the length of a bit sequence that represents each group (e.g., a group indicating one bit combination) is k, the number m of bit values output from the logic gate network 313 may be g×k. Here, k may be the number of bits used for representing the probability (or raw probability score) for each bit combination and may be an integer greater than or equal to 1. The length of input bitstream according to the coding system described above, the number of output bit values, the length of bit sequence representing each group, and the number of groups may be design parameters and may vary depending on the design.

The raw probability score generator 315 may generate the raw probability score 306 from the output bit values of the logic gate network 313. The raw probability score 306 for each bit combination may be, for example, a score used for computing the length of a probability interval occupied by the bit combination in the probability distribution. For example, the raw probability score 306 may be converted into the length of a probability interval of a normalized probability distribution through the normalization 331 described below.

The coder 130 according to an embodiment may generate the compressed bitstream 109 from compression-related information (e.g., the raw probability score 306). For example, the coder 130 may perform the normalization 331 and coding 333.

Since the coder 130 performs the normalization 331 on the compression-related information, the coder 130 may convert the compression-related information (e.g., the raw probability score 306) into a value within a range (e.g., between 0 and 1). The coder 130 may convert the raw probability score 306 for each bit combination into the length of a probability interval occupied by the bit combination in the probability distribution through the normalization 331. The normalization 331 may include an operation based on a nonlinear function. For example, the operation according to the nonlinear function used for the normalization 331 may include a softmax operation. However, embodiments are not limited thereto, and in some embodiments, the nonlinear function may include a sigmoid function. In an exponential function of the softmax function, since the maximum value of an output is not bounded, an output value of the softmax function may increase. The exponential function of the softmax function may be changed to a sigmoid function, which is a bounded nonlinear function.

The nonlinear function in the normalization 331 described above may be implemented as an operator for the operation, but embodiments are not limited thereto, and in some embodiments, the nonlinear function may be implemented as look up table (LUT) circuitry. The electronic device may generate an approximated value using an LUT that models the nonlinear function in the coder 130 without actually performing a complex operation of the nonlinear function.

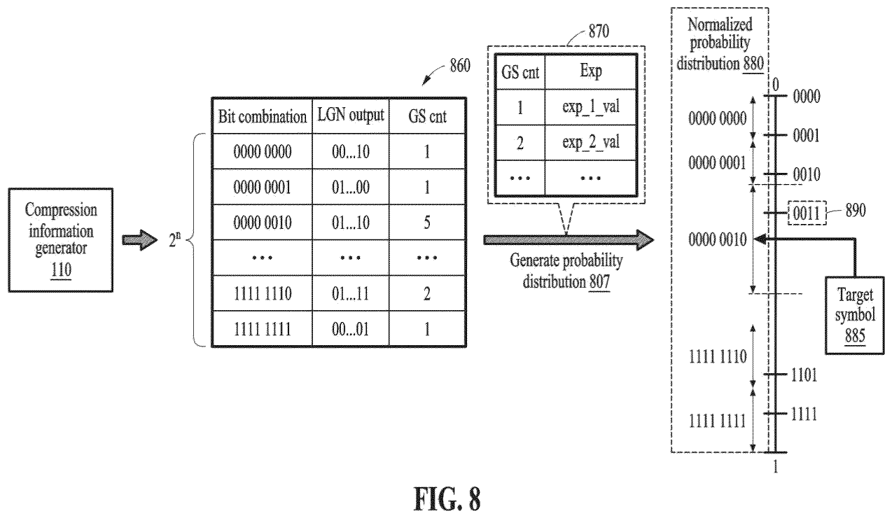

The coder 130 may perform the coding 333 based on a result of normalizing 331 the raw probability score 306. The result of normalizing 331 the raw probability score 306 may include a cumulative distribution function (CDF) in which normalized probability intervals are accumulated. For example, the coder 130 may generate the compressed bitstream 109 by performing entropy coding based on the probability distribution. The entropy coding may include arithmetic coding, asymmetric numeral systems coding, or other probability-based codings. The coder 130 may generate the compressed bitstream 109 corresponding to the symbol according to the probability distribution (e.g., the PDF and/or CDF) based on a normalized 331 probability range. Herein, arithmetic coding is described with reference to FIG. 8 below as an example of entropy coding based on the probability distribution.

Although the present disclosure mainly describes an example of performing an operation according to a nonlinear function, embodiments are not limited thereto. In some embodiments, an operation according to the nonlinear function may be omitted for normalization. In this case, the coder 130 may sum raw probability scores determined for each bit combination based on the logic gate network. The coder 130 may normalize the raw probability scores for each bit combination using a result (e.g., a summed value) of summing the raw probability scores. The coder 130 may determine a CDF of bit combinations based on the normalized probability score. The coder 130 may generate a compressed bitstream for an input bit sequence using the CDF of the bit combinations.

FIG. 4 illustrates a bitstream generator according to an embodiment.

The bitstream generator 311 may convert an input symbol 401 (e.g., “4”) into an input bitstream 403, as described above with reference to FIG. 3. The bitstream generator 311 may also be referred as a scalar to bit converter.

In the example shown in FIG. 4, the bitstream generator 311 may receive a scalar value of “4”. The bitstream generator 311 may generate a bitstream of a number of bits (e.g., 8 bits corresponding to 1 byte) representing the scalar value. The number of bits may be predetermined. The bitstream generator 311 may generate a bitstream of “0000 0100”. A least significant bit (LSB) may indicate a bit value of the ones place, and a most significant bit (MSB) may indicate a bit value of the 2\hat{ }7th place. The bitstream generator 311 may be implemented as a set of one or more logic circuits, but is not limited thereto.

FIG. 5 illustrates an operation according to a logic gate network according to an embodiment.

A logic gate network 530 (e.g., the logic gate network 313 of FIG. 3) according to an embodiment may generate output bit values 540 from an input bitstream 503. The input bitstream 503 may include bitstreams 503-1 and 503-9 corresponding to a plurality of input symbols (e.g., “ABC”). The bitstream 503-1 may be a bitstream (e.g., “0000 0111”) representing symbol “A”, and the bitstream 503-9 may be a bitstream representing symbol “C”.

The logic gate network 530 may include a plurality of nodes, and each node may be a logic gate. The logic gate network 530 may be a binary logic gate network, and each of logic gates 535 of the logic gate network 530 may be a logic gate performing a binary logic operation.

For example, the logic gate network 530 may include a number of input nodes equal to the number of bits of the input bitstream 503. An input node of an input layer 531 may be an input terminal for receiving bit values of the input bitstream 503. The bit values received by the input node may be input to the logic gates 535. In the example shown in FIG. 5, the input bitstream 503 of ((the number of input symbols)×(n bits)) bits may be provided to the input nodes. The input node may be, for example, a buffer gate.

Each node (e.g., a logic gate) of the logic gate network 530 may generate a result value of performing a binary operation on two bit values transmitted from a node (e.g., an input node) of a previous layer. The node may transmit the result value of the binary operation to a node of a subsequent layer. The logic gate network 530 may generate an output bit value of a node (e.g., an output node) of an output layer 539 by repeating the transmission of a result value of performing a binary operation in the nodes (e.g., the logic gates 535). Since the type of logic gates included in the logic gate network 530 is determined based on training for data compression, the output of the logic gate network 530 may indicate information (e.g., the compression-related information) corresponding to compression of the input bitstream 503. For example, the logic gate network 530 may generate the compression-related information corresponding to the probability that bit combinations according to the coding system occur subsequent to the input symbols represented by the input bitstream 503, as the output bit values 540.

The output layer 539 may include m output nodes for generating the output bit values 540 for the bit combinations. In this case, m may be an integer greater than or equal to g. For example, the output nodes of the output layer 539 may be grouped into g bit groups to represent probability-related information for each of the g bit combinations. The bit group and the bit combination according to the coding system may have a one-to-one correspondence. Each bit group may include k output nodes as described above. The probability-related information for each bit combination may be information related to the length of a probability interval that the bit combination occurs subsequent to the input symbols, and may be represented as a bit sequence of k bits. Since an output from one node (e.g., the logic gate) is a 1-bit value, k output nodes may be grouped as a group (e.g., the bit group) for representing the probability information for one of the bit combinations. The output bit values 540 of each bit group may be used for computing the raw probability score of the bit combination (e.g., “0000 0100”) corresponding to the bit group, as described above. Accordingly, the output layer 539 may include m output nodes.

As described below, the raw probability score may be determined from the output bit values 540 corresponding to each of the plurality of bit groups. For example, a raw probability score 561 may be determined from the output bit values of a bit group 541, and a raw probability score 569 may be determined from output bit values of another bit group. Compression-related information 560 may include g raw probability scores.

According to an embodiment, an arrangement of the logic gates 535 may be fixed in advance prior to training. The logic gate network 530 may be a network in which the logic gates 535 are arranged, wherein the type of the logic gates 535 is determined based on training the differentiable logic gate network 530 (e.g., a neural network that models the logic gate network 530) for a target compression operation. However, embodiments are not limited thereto, and in some embodiments, the arrangement of the logic gates 535 may be updated during the training process. The types of the logic gates 535 of the logic gate network 530 and the connection among the logic gates 535 may be determined based on training of the differentiable logic gate network 530 corresponding to the logic gate network 530. The training using the differentiable logic gate network 530 is described with reference to FIG. 9.

For reference, as described below with reference to FIG. 9, each logic gate included in the logic gate network 530 may be modeled as a node of the neural network, and the connection among the logic gates 535 may be modeled as an edge of the neural network. Since a binary logic gate has two inputs and one output, each node of the neural network that models the logic gate network 530 may be connected to two nodes of a previous layer and one node of a subsequent layer.

FIG. 6 illustrates an example of counting the number of bits as a raw probability score, according to an embodiment.

A compression device (e.g., the compression device 100 of FIG. 1) according to an embodiment may include a raw probability score generator that is configured to determine a score (e.g., a raw probability score) to be compression-related information, wherein the score corresponds to a probability based on counting the number of bit values in a bit group 641 corresponding to each bit combination. The number of bits may be predetermined. The bit value may be, for example, a bit value of “1”. The raw probability score generator for counting the number of bit values may also be referred to as a bit counter 650. The bit counter 650 may be implemented as a set of one or more logic circuits (e.g., adders).

The bit counter 650 may count the number of bit values of output bit values of the bit group 641. For example, in FIG. 6, the logic gate network may output output bit values of “0000 0111” for the bit group 641. Since the number of “1”s in “0000 0111” is 3, the bit counter 650 may output a scalar value 661 of “3”. For example, the bit counter 650 may sum bit values of “0000 0111” without distinguishing bit positions. An output of the bit counter 650 may be referred to as a group sum. The output may be referred to as a group sum because the output is determined by summing the bit values belonging to the bit group 641. The compression device may output g group sums as raw probability scores for g bit groups using the bit counter 650.

However, the example of the raw probability score is not limited to the group sum described above. FIG. 7 illustrates an example of converting output bit values into scalar values in another manner.

FIG. 7 illustrates an example of determining a scalar value as a raw probability score, according to an embodiment.

A compression device (e.g., the compression device 100 of FIG. 1) according to an embodiment may include a raw probability score generator that is configured to determine a score corresponding to a probability based on a scalar value 761 determined using a bit position and a bit value of a bit group 741 corresponding to each of bit combinations. The raw probability score generator that performs scalar conversion using positional importance (e.g., a bit position) and a bit value may also be referred to as a scalar calculator 750 or a scalar to bit converter. The scalar calculator 750 may be implemented as a set of one or more logic circuits.

The scalar calculator 750 may determine a raw probability score by summing calculated values based on bit positions and bit values of output bit values of the bit group 741. For example, in FIG. 7, the logic gate network may output output bit values of “0000 0111” for the bit group 741. The LSB may indicate a bit value of the ones place, and the MSB may indicate a bit value of the 2\hat{ }7th place. For example, the scalar calculator 750 may calculate a scalar value 761 of 2\hat{ }2+2\hat{ }1+2\hat{ }0=4+2+1=7 as a raw probability score. The compression device may output g raw probability scores as raw probability scores for g bit groups 741 using the scalar calculator 750.

FIG. 8 illustrates an example of generating a compressed bitstream from a raw probability score, according to an embodiment.

A compression device (e.g., the compression device 100 of FIG. 1) according to an embodiment may include a coder (e.g., the coder 130 of FIG. 1) that determines a probability distribution function (PDF) of bit combinations based on a score corresponding to a probability. The coder may perform normalization and coding.

The coder may perform probability distribution generation (i.e., may generate a probability distribution 807). For example, the coder may normalize compression-related information 860 transmitted from the compression information generator 110 including the logic gate network. The compression-related information 860 may include raw probability scores (e.g., a group sum count (GS cnt)) of bit combinations according to the coding system. In the example shown in FIG. 8, the compression-related information 860 may include a group sum (GS) determined for g bit combinations. In FIG. 8, the compression-related information 860 is illustrated in the form of a table for clear understanding, but embodiments are not limited thereto. An example where a raw probability score 861 for a bit combination of “0000 0010” among the bit combinations is 5 is described.

The coder may normalize the score corresponding to the probability based on an LUT 870 corresponding to a nonlinear function. The coder may, for example, convert the raw probability score corresponding to each bit combination into a normalized probability interval so that a CDF that accumulates probability intervals for all bit combinations has a range between 0 and 1. For example, the coder may convert a scalar value indicating the raw probability score into a probability (e.g., the probability interval) through a softmax function operation. The coder may include the LUT 870 or an operator (e.g., an ALU) for an operation of the nonlinear function. Herein, an example where the coder includes the LUT 870 is mainly described, but is not limited thereto.

The LUT 870 may include information indicating a mapping relationship between the raw probability score and a result value of an exponential function. The round LUT 870 may include information indicating a mapping relationship between the raw probability score and a result value of the exponential function that is converted into an integer value by rounding. The coder may also include the round LUT 870 for normalization. For example, an example of the LUT 870 that models a nonlinear function (e.g., the exponential function of the softmax function) in FIG. 8 may include information indicating a mapping relationship between the raw probability score and an exponential result value (e.g., exp_1_val and exp_2_val). For example, the length of a probability interval corresponding to the exponential result value exp_2_val may be calculated to be 2/15. The length of the probability interval when the raw probability score is 5 may be 2/15. In this case, since the raw probability score for the bit combination of “0000 0010” is 5, the coder may determine the length of the probability interval for the bit combination of “0000 0010” to be 2/15. The sum of the lengths of probability intervals of all bit combinations may be 1.

According to an embodiment, the coder may include an ALU that is configured to perform the probability distribution generation 807. In an embodiment, the ALU may be coded to perform the probability distribution generation 807. However, embodiments are not limited thereto, and in some embodiments, the coder may send a request to a host device (e.g., a central processing unit (CPU) as a host processor) for the probability distribution generation 807.

The coder may generate a compressed bitstream 890 corresponding to a target symbol 885 based on a normalized probability distribution 880 determined for the bit combinations of the coding system. The normalized probability distribution 880 may indicate a distribution of probabilities that symbols occur subsequent to input symbols (e.g., “ABC”) in a symbol sequence (e.g., “ABCD”) as described above. In FIG. 8, a CDF in which probability intervals of bit combinations (e.g., “0000 0000”, “0000 0001”, “0000 0010” to “1111 1110”, and “1111 1111”) indicating symbols according to the coding system are accumulated is illustrated as the normalized probability distribution 880 as an example.

The coder may generate the compressed bitstream 890 based on arithmetic coding using the normalized probability distribution 880. The coder may determine the compressed bitstream 890 based on a value belonging to the probability interval corresponding to the target symbol 885 among the probability intervals in which each bit combination occurs subsequent to the input symbols. For example, in the example shown in FIG. 8, the probability interval of the bit combination of “0000 0010” may be a range greater than or equal to 2/15 and less than 4/15 (e.g., [0.1333, 0.2667)). When the target symbol 885 (e.g., “D”) is represented as a bit combination of “0000 0010”, the probability interval in which the target symbol 885 occurs subsequent to the input symbols may be a range greater than or equal to 2/15 and less than 4/15. The compressed bitstream 890 indicating the target symbol 885 may be determined to be a bitstream indicating a value within the probability interval in which the target symbol 885 occurs. When the normalized bit combination is represented by 4 bits, the MSB may be the 1/2 place and the LSB may be 1/2\hat{ }4. In this case, “0011” may indicate a value of 1/2\hat{ }3+1/2\hat{ }4=0.1875. The range greater than or equal to 2/15 and less than 4/15 may be represented as, for example, “0011”. Consequently, an 8-bit bitstream of “0000 0010” may be compressed into the 4-bit compressed bitstream 890 of “0011”. Accordingly, the number of bits (e.g., 4 bits) of the compressed bitstream 890 for each symbol of a data stream may be less than the number of bits (e.g., 8 bits) of the original bitstream of the symbol.

Table 2 below shows a performance comparison when an operation (e.g., the exponential function of softmax) according to the nonlinear function performed by the coder is replaced with the LUT.

TABLE 2

| | GCR |
|---|---|
| Exponential operator | 3.1046 |
| LUT | 3.1057 |

As shown in Table 2, since the GCR when using the exponential operator is 3.1046, and the GCR when using the LUT is 3.1057, there is only a slight difference of three decimal places. Accordingly, the coder may include the LUT 870 instead of the exponential operator of softmax.

With reference to FIGS. 1 to 8, the operation of generating a compressed bitstream for a target symbol is mainly described. An operation of determining the target symbol by decoding a compressed bitstream may be performed using the logic gate network. According to an embodiment, the compression device may receive a compressed stream including a target stream (e.g., a compressed bitstream corresponding to “D”) to be decoded. In the compressed stream, an input bitstream (e.g., an uncompressed bitstream) representing the input symbols (e.g., “ABC”) preceding the target symbol corresponding to the target stream may be given in advance or may be obtained by a preceding decoding operation. When a portion corresponding to the input bitstream is removed from the compressed stream, the target stream may be identified. Similar to the description provided above with reference to FIG. 5, the compression device may input the uncompressed input bitstream to the logic gate network, thereby generating the compression-related information about the probability that the symbols occur subsequent to the input symbols. Similar to the description provided above with reference to FIG. 8, the compression device may obtain a normalized probability distribution about the probability that the symbols occur subsequent to the input symbols, from the compression-related information. Contrary to the description of FIG. 8 above, the compression device may use the normalized probability distribution. For example, the compression device may identify a probability interval to which the target stream belongs in the normalized probability distribution. The compression device may determine a bit combination corresponding to the identified probability interval. The determined bit combination may be a bitstream representing the target symbol (e.g., “D”).

FIG. 9 illustrates training using a differentiable logic gate network, according to an embodiment.

A differentiable logic gate network 913 described with reference to FIG. 9 may be a differentiably modeled network of the logic gate network described with reference to FIG. 5 for machine learning-based training. For example, each node of the differentiable logic gate network 913 may perform a real-number operation in which binary logic operators are relaxed. An electronic device (e.g., a training device) may perform a real-number operation according to Table 3 below in each node of the differentiable logic gate network 913. For example, among logic operations, a logic operation AVB of which ID is 8 may be calculated as A+B−AB in training. Table 3 below may indicate a real-number operator corresponding to each of 16 types of logic operations and an operation result thereof. Each real-number operator may be differentiable.

TABLE 3

| | | Real-number | | | | |
|---|---|---|---|---|---|---|
| ID | Operation type | operator | 0 | 1 | 10 | 11 |
| 0 | False | 0 | 0 | 0 | 0 | 0 |
| 1 | A∧B | A · B | 0 | 0 | 0 | 1 |
| 2 | ¬(A => B) | A − AB | 0 | 0 | 1 | 0 |
| 3 | A | A | 0 | 0 | 1 | 1 |
| 4 | ¬(A <= B) | B − AB | 0 | 1 | 0 | 0 |
| 5 | B | B | 0 | 1 | 0 | 1 |
| 6 | A⊕B | A + B − 2AB | 0 | 1 | 1 | 0 |
| 7 | A∨B | A + B − AB | 0 | 1 | 1 | 1 |
| 8 | ¬(A∨B) | 1 − (A + B − AB) | 1 | 0 | 0 | 0 |
| 9 | ¬(A⊕B) | 1 − (A + B − 2AB) | 1 | 0 | 0 | 1 |
| 10 | ¬B | 1 − B | 1 | 0 | 1 | 0 |
| 11 | A <= B | 1 − B + AB | 1 | 0 | 1 | 1 |
| 12 | ¬A | 1 − A | 1 | 1 | 0 | 0 |
| 13 | A => B | 1 − A + AB | 1 | 1 | 0 | 1 |
| 14 | ¬(A∧B) | 1 − AB | 1 | 1 | 1 | 0 |
| 15 | True | 1 | 1 | 1 | 1 | 1 |

Each node of the differentiable logic gate network 913 may be connected to two previous nodes or one previous node. An output of each node may be connected to a subsequent node. The number of input nodes of an input layer may be n, which is the number of bits of an input bitstream as described above with reference to FIG. 5. The number of output nodes of an output layer may be m. Each node of the differentiable logic gate network 913 may be connected to other nodes 913-1 according to the constraint described above. A connection 913-3 among the nodes 913-1 of the differentiable logic gate network 913 may be randomly determined under the constraint described above. The electronic device may perform parameter update on the randomly connected differentiable logic gate network 913 based on forward propagation and backpropagation using training data.

The electronic device according to an embodiment may perform a real-number operation corresponding to the 16 types of logic operators described above, in each node of the differentiable logic gate network 913. The electronic device may perform 16 types of real-number operations on two values input to one of nodes in a forward propagation process of training. The electronic device may generate real-number operation results corresponding to 16 logic operators for each node. The electronic device may determine a weighted sum of the real-number operation results to be an output for the subsequent node according to Equation 1 below.

$${a}^{′} = {\sum }_{i - 0}^{15} {p}_{i} \cdot {f}_{i} ( {a}_{1} , {a}_{2} ) = {\sum }_{i = 0}^{15} \frac{{e}^{{w}_{i}}}{{\sum }_{j} {e}^{{w}_{j}}} \cdot {f}_{i} ( {a}_{1} , {a}_{2} ) \qquad [ Equation 1 ]$$

Equation 1 described above may indicate an operation performed in one of the nodes. Here, a′ may indicate a value transmitted to a subsequent node of the corresponding node, a₁ and a₂ may indicate values input to the corresponding node, fᵢ may indicate a real-number operation corresponding to an i-th logic operator among 16 logic operators, i may be an integer between 0 and 15, pᵢ may indicate a weight multiplied by an i-th real-number operation result, and wᵢ may be a parameter indicating the possibility that the operation to be performed in the node is the i-th logic operator and may be updated during the training process. Since a 16-dimensional probability value converted from wᵢ through softmax denotes the probability that each logic operator is selected, wᵢ may be interpreted as an index for determining a relative ratio of the probability. The electronic device may convert wᵢ into a probability through a softmax function and may multiply the probability by each operation result as a weight. The values fᵢ and wᵢ described above may be differentiable. In the example shown in FIG. 9, a parameter 913-5 in which w₀ is 0.04, wⱼ is 0.01, and w₁₅ is 0.02 is illustrated.

The training data may include a bitstream to be compressed and a ground truth (GT) compression result as a compression result. The electronic device may generate an input bitstream based on the bitstream generator 311 from a symbol sequence 901. The electronic device may propagate bit values of the input bitstream to the nodes 913-1 of the differentiable logic gate network 913. The electronic device may perform real-number operations corresponding to multiple types of logic operators (e.g., 16 types of logic operators) in each node. The electronic device may calculate a weighted sum of 16 operation values according to Equation 1 described above in each node. The electronic device may generate output bit values in the differentiable logic gate network 913 by repeating calculation and propagation of operations results according to Equation 1 in the nodes 913-1.

The electronic device may generate compression-related information 906 using the raw probability score generator 315 of a compression information generator 910 from the output bit values. The coder 130 may generate a compressed bitstream 909 from the compression-related information 906. Similar to the description provided above with reference to FIGS. 1 to 8, the electronic device may predict the compressed bitstream 909 representing the target symbol, based on a normal probability distribution about the probability that the symbols occur subsequent to the input symbols. The electronic device may calculate an objective function value 908 (e.g., a loss value) based on a GT bitstream 907 and the compressed bitstream 909. The electronic device may update a parameter of each node of the differentiable logic gate network 913 based on backpropagation of the calculated objective function value 908. As described above, the parameter of each node may indicate the probability that the node indicates one of multiple logical operators. For example, FIG. 9 illustrates an example where the parameter 913-5 has the highest probability of being a true operation, 0.3. The electronic device may repeat the parameter of the node so that the objective function value 908 converges. However, embodiments are not limited thereto, and in some embodiments, the electronic device may update the parameter for a iteration number. The iteration number may be predetermined.

When the training is completed, the electronic device may determine a logic operator of each node based on the parameter of the node. For example, for the node, the electronic device may select a logic operator with the highest probability from trained parameters of the node. For example, the electronic device may determine a one-hot vector with the highest probability value from probability values corresponding to 16 logic operators. The electronic device may fix a logic gate disposed in the nodes 913-1 according to the one-hot vector. The types of logic gates for data compression and the connection 913-3 among the logic gates may be determined through the differentiable logic gate network 913 used for training. A logic gate network for inference may be physical circuitry of a network in which determined types of logic gates through training of the differentiable logic gate network 913 are arranged, as described above. For reference, the number (e.g., the number of nodes in training) of logic gates included in the logic gate network may be determined depending on the configuration.

The device for performing training (e.g., the training device) described with reference to FIG. 9 may be a separate device from the electronic device including the compression device described with reference to FIGS. 1 to 8. For example, in the training device, the logic gates may be determined through the training described with reference to FIG. 9. The compression device to which the logic gate network including the determined logic gates is mounted may be manufactured. The electronic device may include the compression device and may perform data compression using the compression device.

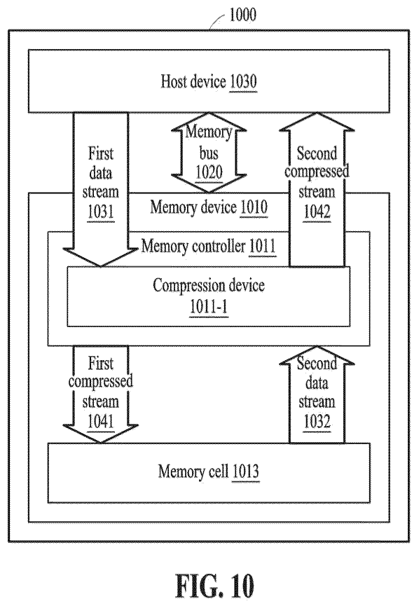

FIG. 10 illustrates an example of a configuration of an electronic device according to an embodiment.

An electronic device 1000 according to an embodiment may include a host device 1030 and a memory device 1010.

The host device 1030 may send a request to the memory device 1010 to read and/or write data. For example, the host device 1030 may send a read request and/or write request for reading and/or writing data to the memory device 1010 via a memory bus 1020.

The memory device 1010 may perform data reading and/or writing on a memory cell 1013 based on the received request (e.g., the read request and/or the write request) from the host device 1030. The memory device 1010 may include a memory controller 1011 and the memory cell 1013.

The memory cell 1013 may form a memory area in which data is stored. The memory area may indicate an area (e.g., a physical area) in a memory chip of the physical memory device 1010 where data may be read and/or written. The memory area may be disposed on a memory die (e.g., or a core die) of the memory device 1010. The memory device 1010 may cooperate with the host device 1030 (e.g., a host processor) to process data in the memory area. For example, the memory device 1010 may control the memory area based on an instruction or command received from the host processor. The host processor may comprise a central processing unit (CPU), a microcontroller, a microprocessor, dedicated hardware logic, an application specific integrated processor (ASIC), or the like. The memory device 1010 may be separated from the host device 1030.

The memory controller 1011 may process a request received from the host device 1030. For example, the memory controller 1011 may perform data reading and/or writing on the memory cell 1013. The memory controller 1011 according to an embodiment may include a compression device 1011-1. In an embodiment, the compression device 1011-1 may correspond to the compression device 100 and/or the compression device 300 described above with respect to FIGS. 1-9. The memory controller 1011 may compress the data via the compression device 1011-1 before reading data from the memory cell 1013 or writing the data to the memory cell 1013.

For example, in response to the write request of the host device 1030, the compression device 1011-1 may generate a compressed bitstream corresponding to a symbol of a data stream received from the host device 1030. The compression device 1011-1 may store the compressed data including the compressed bitstream in the memory cell 1013. As described above, the number of bits of the compressed bitstream for each symbol of the data stream may be less than the number of bits of the original bitstream of the symbol. For example, in FIG. 10, the host device 1030 may transmit a first data stream 1031 to the memory device 1010. The memory device 1010 may generate a first compressed stream 1041 from the first data stream 1031 via the compression device 1011-1. The number of symbols indicated by the compressed bitstreams stored in the memory area of the memory cell 1013 may be greater than the number of symbols indicated by the original bitstreams stored in a memory area having the same capacity. In other words, since the same number of symbols are indicated with fewer bits in the compressed bitstream, then it is possible to store a greater number of symbols in the memory than in a non-compressed bitstream, assuming a same size memory is used for the compressed bitstream and the non-compressed bitstream. The memory capacity occupied by the first compressed stream 1041 may be less than the memory capacity occupied by the first data stream 1031. Accordingly, more information may be stored in a limited memory capacity.

In some embodiments, in response to the read request of the host device 1030, the compression device 1011-1 may generate a compressed bitstream corresponding to a symbol of a data stream loaded from the memory cell 1013. The compression device 1011-1 may provide compressed data including the compressed bitstream to the host device 1030. For example, in FIG. 10, the memory device 1010 may transmit the data to the host device 1030. The memory device 1010 may load data of a second data stream 1032 from the memory cell 1013. The memory device 1010 may compress the loaded second data stream 1032 using the compression device 1011-1. The memory device 1010 may transmit a second compressed stream 1042 obtained by compressing the second data stream, to the host device 1030. In data transmission, a memory bandwidth occupied by the second compressed stream 1042 may be less than a memory bandwidth occupied by the second data stream 1032. Accordingly, more information may be rapidly transmitted in a limited memory bandwidth.

The embodiments described herein may be implemented using a hardware component, a software component and/or a combination thereof. A processing device (such as the host device 1030, the compression device 100, 300, 1011-1, and the memory controller 1011) may be implemented using one or more general-purpose or special-purpose computers, such as, for example, a processor, a controller and an ALU, a digital signal processor (DSP), a microcomputer, an FPGA, a programmable logic unit (PLU), a microprocessor, or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular. However, one skilled in the art will appreciate that a processing device may include multiple processing elements and multiple types of processing elements. For example, the processing device may include a plurality of processors, or a single processor and a single controller. In addition, different processing configurations are possible, such as parallel processors.

The software may include a computer program, a piece of code, an instruction, or some combination thereof, to independently or uniformly instruct or configure the processing device to operate as described above with respect to FIGS. 1-10. Software and data may be stored in any type of machine, component, physical or virtual equipment, or computer storage medium or device capable of providing instructions or data to or being interpreted by the processing device. The software also may be distributed over network-coupled computer systems so that the software is stored and executed in a distributed fashion. The software and data may be stored by one or more non-transitory computer-readable recording mediums.

The methods according to the above-described embodiments may be recorded in non-transitory computer-readable media including program instructions to implement various operations of the embodiments described above with respect to FIGS. 1-10. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher-level code that may be executed by the computer using an interpreter.

The above-described hardware devices may be configured to act as one or more software modules in order to perform the operations of the above-described examples, or vice versa.

As described above, although the embodiments have been described with reference to the drawings, a person skilled in the art may apply various technical modifications and variations based thereon. For example, suitable results may be achieved if the described techniques are performed in a different order and/or if components in a described system, architecture, device, or circuit are combined in a different manner and/or replaced or supplemented by other components or their equivalents.

Accordingly, other implementations and modifications are within the scope of the following claims.

What is claimed is:

1. An electronic device comprising:
a compression device that is configured to generate a compressed bitstream from a data stream, the compressed bitstream representing a target symbol from an input bitstream representing an input symbol from the data stream including the input symbol and the target symbol,
wherein the compression device comprises:
a compression information generator that is configured to generate compression-related information on the target symbol from the input bitstream, based on a logic gate network including a plurality of logic gates arranged for data compression; and
a coder that is configured to generate the compressed bitstream corresponding to the target symbol based on the compression-related information.

2. The electronic device of claim 1, wherein the compression-related information comprises a score corresponding to a probability that the input bitstream belongs to each of bit combinations according to a coding system of a symbol.

3. The electronic device of claim 1, wherein the compression-related information comprises a score, and
the compression information generator comprises a raw probability score generator configured to determine the score corresponding to a probability, based on counting a number of bit values in a bit group corresponding to each of bit combinations.

4. The electronic device of claim 1, wherein the compression information generator comprises a raw probability score generator that is configured to determine a score corresponding to a probability, based on a scalar value that is determined using a bit position and a bit value of a bit group corresponding to each of bit combinations.

5. The electronic device of claim 1, wherein the coder is configured to determine a probability distribution function (PDF) of bit combinations, based on a score corresponding to a probability.

6. The electronic device of claim 1, wherein a number of bits of the compressed bitstream is less than a number of bits of a bitstream that represents one of symbols input to the logic gate network.

7. The electronic device of claim 1, wherein each of the plurality of logic gates of the logic gate network is a logic gate performing a binary logic operation.

8. The electronic device of claim 1, wherein at least one of a type of logic gates of the logic gate network or a connection among the logic gates of the logic gate network is determined based on training a differentiable logic gate network corresponding to the logic gate network.

9. The electronic device of claim 1, wherein the data stream is received from a host device, and
wherein the compression device:
in response to a write request of the host device, generates the compressed bitstream corresponding to a symbol of the data stream received from the host device, and
store compressed data including the compressed bitstream in a memory cell.

10. The electronic device of claim 1, wherein the compression device:
in response to a read request of a host device, generates the compressed bitstream corresponding to a symbol of a stored data stream loaded from a memory cell, and
provides compressed data including the compressed bitstream to the host device.

11. A method of operating an electronic device, the method comprising:
generating compression-related information on a target symbol of a data stream from an input bitstream that represents an input symbol of the data stream, based on a logic gate network including a plurality of logic gates arranged for data compression; and
generating a compressed bitstream that corresponds to the target symbol, based on the compression-related information.

12. The method of claim 11, wherein the compression-related information comprises a score, and
wherein the generating of the compression-related information comprises determining the score corresponding to a probability, based on counting a number of bit values in a bit group corresponding to each of bit combinations.

13. The method of claim 11, wherein the generating of the compression-related information comprises determining a score corresponding to a probability, based on a scalar value that is determined using a bit position and a bit value of a bit group corresponding to each of bit combinations.

14. The method of claim 11, wherein the generating of the compressed bitstream comprises determining a probability distribution function (PDF) of bit combinations, based on a score corresponding to a probability.

15. The method of claim 11, wherein the generating of the compressed bitstream comprises generating the compressed bitstream with a fewer number of bits than a number of bits of a bitstream that represents one of symbols input to the logic gate network.

16. The method of claim 11, wherein the generating of the compression-related information comprises generating the compression-related information using the logic gate network including a logic gate performing a binary logic operation.

17. The method of claim 11, wherein at least one of a type of logic gates of the logic gate network or a connection among the logic gates of the logic gate network is determined based on training a differentiable logic gate network corresponding to the logic gate network.

18. The method of claim 11, wherein the data stream is received from a host device, and
wherein the generating of the compressed bitstream comprises, in response to a write request of the host device, generating the compressed bitstream corresponding to a symbol of the data stream received from the host device, and
wherein the method further comprises storing compressed data including the compressed bitstream in a memory cell.

19. The method of claim 11, wherein the generating of the compressed bitstream comprises, in response to a read request of a host device, generating the compressed bitstream corresponding to a symbol of a stored data stream loaded from a memory cell, and
wherein the method further comprises providing compressed data including the compressed bitstream to the host device.

20. A non-transitory computer-readable storage medium storing instructions that, when executed by a processor, cause the processor to perform the method of claim 11.
